(19) United States
(12) Patent Application Publication
(10) Pub. No.: US 2015/0123433 A1
(43) Pub. Date: May 7, 2015

(54) Holder For Personal Electronic Devices

(71) Applicant: Astronics Advanced Electronic Systems Corp., Kirkland, WA (US)

(72) Inventors: John S. Lamb, JR., Bothell, WA (US); Michael Hettich, Sammamish, WA (US)

(73) Assignee: Astronics Advanced Electronic Systems Corp., Kirkland, WA (US)

(21) Appl. No.: 14/070,189

(22) Filed: Nov. 1, 2013

(51) Int. Cl. B60R 11/02; B64D 11/06; B64D 11/00; H05K 5/00

(52) U.S. Cl. CPC B60R 11/0229; H05K 5/0017; B64D 11/06; B64D 11/0015; B64D 2011/0662
USPC 297/188.05; 361/807; 297/188.04

(57) ABSTRACT

A display apparatus for the presentation to a user of a personal electronic device (PED), including a horizontal flexible member effective for the insertion of a portion of a PED so that the display of the PED is orientated towards a user. The disclosed apparatus is useful in conjunction with passenger seating within a passenger vehicle, such as an aircraft. In some embodiments, an adjustment mechanism allows for adjustment of the orientation of the display of the PED.

### FIELD OF THE DISCLOSURE

The subject matter of the present disclosure generally relates to mechanisms to capture portable electronic devices, and more particularly relates to mechanisms to temporarily affix portable electronic devices to the backs of passenger seats and orient those devices towards users.

### BACKGROUND OF THE DISCLOSURE

Previously, some passenger vehicles, such as aircraft and buses, have incorporated built-in video entertainment units. Such units provide a leisure activity for traveling passengers that helps them to pass their time and have a more satisfactory travel experience. Initially, such units were typically installed in a shared-unit setup, whereby one video display would service multiple passengers. More recently, and in part because of technological advances such as liquid crystal displays (LCDs), many passenger vehicles now incorporate individual entertainment units for each passenger, which are often located in the upper seatbacks of passenger seats. For example, many passenger aircraft now have inflight entertainment (IFE) devices, which are well known in the art. Some individual displays even allow passengers to custom tailor their content programing. However, often only a limited number of programming options are available on such displays. For instance, on a particular passenger flight there may only be three movies from which each passenger must choose.

Personal electronic devices (PEDs), such as tablet computers, smartphones and mobile gaming platforms, offer several advantages over IFE and similar devices. One such advantage is that PEDs normally belong to the user, so that the user is able to select a device based on their own desired functionality. Also, PEDs usually allow the user to store and customize their own content, so that they are not limited to the content then-stored in a IFE or similar device. Another advantage of PEDs is that they are mobile and therefore usable in a variety of environments. For instance, passengers on aircraft may, for the most part, utilize PEDs at will. Technological progress has brought and continues to bring significant increases in the functionality and computing ability of PEDs. For these reasons, users place increasing importance on consistent access to such devices.

There are, however, some disadvantages to the use of PEDs in comparison to IFE or like devices. For example, in airplanes, PEDs normally must be held in the passenger's hands or placed on a fold-down tray table. Holding a mobile device for extended periods can lead to passenger fatigue and discomfort. The use of a tray table may not provide an optimum viewing angle, and in any event, the tray table is often occupied during in-transit meals, during which passengers still desire the use of their PEDs.

There exists limited options for addressing these concerns. For example, U.S. Pat. No. 8,210,605 to Hough et al. discloses a holster for a passenger seat that has a rear face and a peripheral wall that, together, define a pocket that can hold an electronic device. The holster is moveable between stowed and deployed positions. However, the device of Hough has several disadvantages. Among other things, the use of hardened materials may create potentially harmful or deadly obstructions during high impulse impacts, such as plane crashes. In such situations, passenger-users are susceptible to hitting their extremities, especially their head, on such units, even when not using them to hold their PEDs. The design of U.S. Pat. No. 8,210,605 would also be expected to require moving parts and even the replacement of pre-existing seating units. The disclosure of U.S. Pat. No. 8,210,605 is hereby incorporated by reference in its entirety.

The subject matter of the present disclosure is directed to overcoming, or at least reducing the effects of, one or more of the problems set forth above.

### BRIEF SUMMARY OF THE DISCLOSURE

Disclosed is an apparatus, made from flexible material, that may be attached to or incorporated into seatbacks and that allows the hands-free use of PEDs.

The apparatus is a horizontal strap or slot in a seatback or similar support that allows a portion of a PED to be inserted through the strap or into the slot so that the PED is presented for viewing. In certain embodiments, the PED's display angle can be adjusted by repositioning an adjustment mechanism, such as a flexible strap. Such a feature is useful when the seat from which the PED is presented is in a reclined position. The position of this adjustment strap and therefore, the angle of the device's screen, may optionally be fixed using hook-and-loop tape (aka, Velcro™), snaps, rivets, or comparable mechanisms. The disclosed subject matter utilizes flexible materials, which are advantageous over hard materials when considering the safety of passengers during a crash or other emergency situation. On an airplane, the disclosed subject matter has the additional benefit that passengers may simultaneously utilize their tray table and a PED.

### BRIEF DESCRIPTION OF THE DRAWINGS

The foregoing summary, preferred embodiments, and other aspects of the subject matter of the present disclosure will be best understood with reference to a detailed description of specific embodiments, which follows, when read in conjunction with the accompanying drawings, in which:

FIG. 1 is a illustrative depiction of an embodiment, having a strap and hook and loop adjustment mechanism, before insertion of a PED.

FIG. 2 is an illustrative depiction of the embodiment of FIG. 1 after the insertion of a portion of a PED.

FIG. 3 is an illustrative depiction of an embodiment that is a removable harness that can fit onto a seatback.

FIG. 4 is an illustrative depiction of an embodiment, having a slit and a hook and loop adjustment mechanism, before insertion of a PED.

FIG. 5 is an illustrative depiction of the embodiment of FIG. 4 after the insertion of a portion of a PED.

FIG. 6 is an illustrative depiction of an embodiment that is a removable cover that can be fit onto a seatback.

FIG. 7 is an illustrative depiction of the use of an adjustment mechanism in various positions.

FIG. 8 is an illustrative depiction of an embodiment aircraft passenger seat.

Like reference numbers and designations in the various drawings indicate like elements.

### DETAILED DESCRIPTION OF THE DISCLOSURE

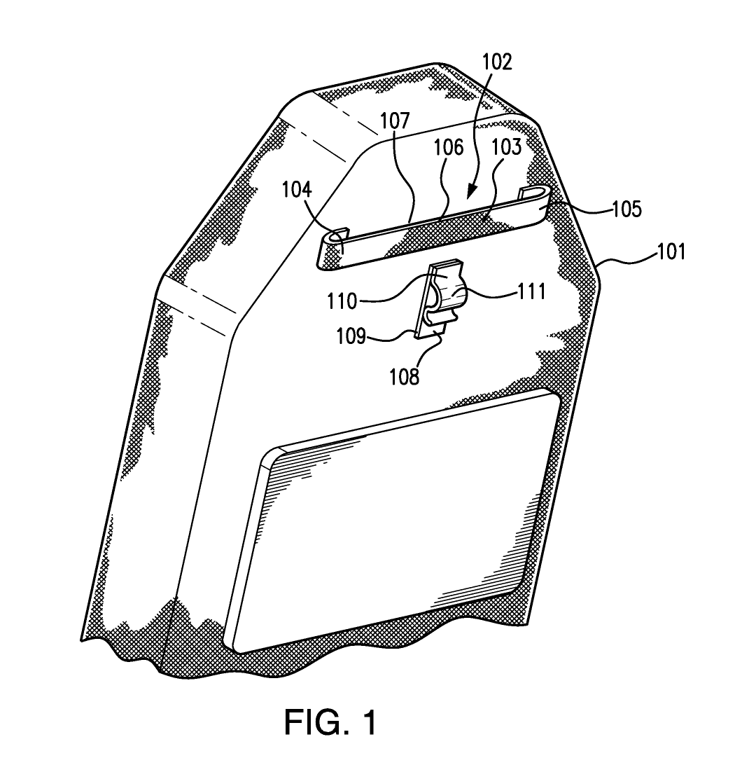

FIG. 1 depicts an embodiment in which seat 101 has support 102, which in this case is the seatback of seat 101. Flexible member 103 is affixed at a first end 104 and second end 105, with mid-portion 106 disposed between first end 104 and second end 105 and spaced by gap 107 from support 102. Flexible member 103 is constructed of a substantially flexible material, such as leather, fabric, and certain flexible plastics or rubbers. Adjustment mechanism 108 allows the adjustment of the orientation of PEDs that are inserted into gap 107. In the embodiment, adjustment mechanism 108 is a repositionable flexible strap. It should be understood that various other means may be used to adjust the orientation of PEDs inserted into gap 107. In the embodiment, adjustment mechanism 108 is made up of hook strap 109 and loop strap 110. Hook strap 109 is affixed to support 102. Loop strap 110 is affixable to hook strap 109 such that bump 111, which protrudes from support 102, can be effectively formed. In contrast, a two strap system could utilize snaps to adjust the size and potion of bump 111. Optionally, the disclosed subject matter can be positioned within an aircraft, so that support 102 is the seatback of a passenger seat.

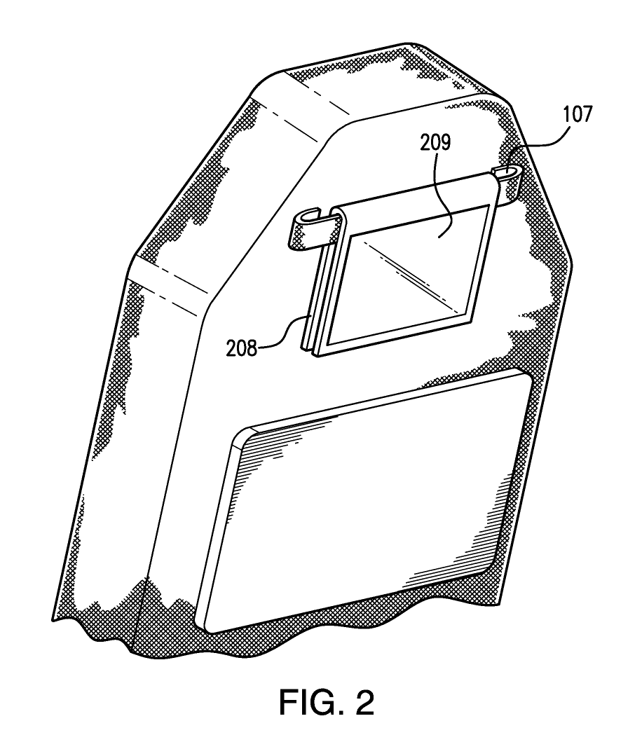

FIG. 2 illustrates the embodiment of FIG. 1, with PED portion 208 of PED 209 inserted into gap 107. In the embodiment, PED portion 208 is the hinged cover of PED 209.

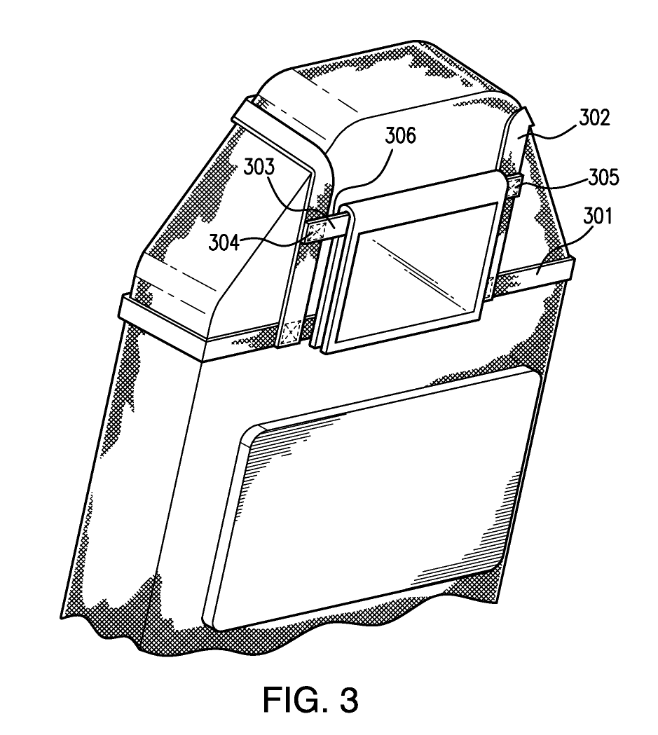

FIG. 3 is an illustrative depiction of an embodiment in which removable harness 301 has support 302. Optionally, an embodiment utilizing a removable harness would function similarly to the embodiment of FIG. 1, only instead of the support being the portion of a seatback, it is part of a removable harness. Flexible member 303 is affixed to support 302 at first end 304 and second end 305, with mid-portion 306 disposed between. The use of such an embodiment may facilitate the retrofitting of vehicles to make use of the disclosed subject matter.

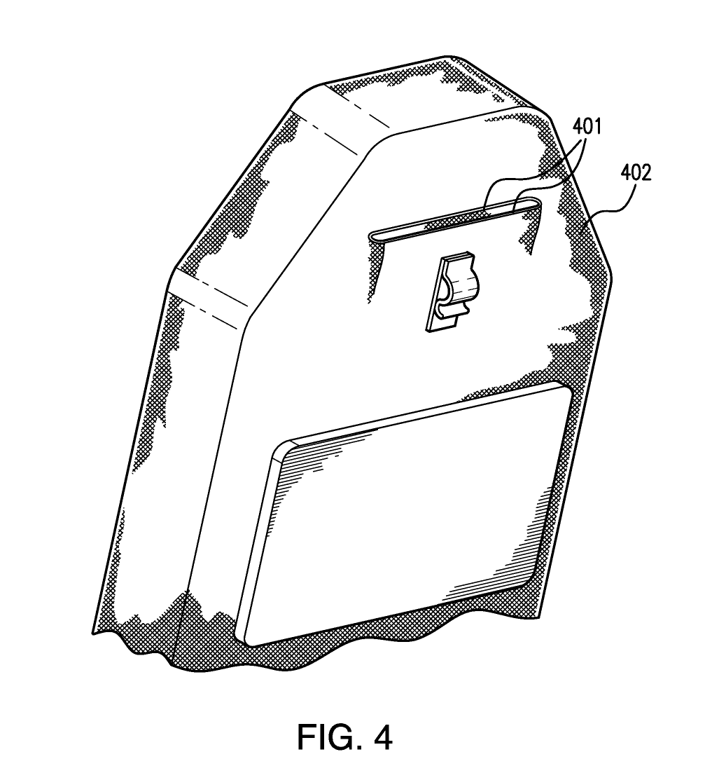

FIG. 4 is an illustrative depiction of another embodiment, having flexible member 401 that is a substantially horizontal slit in support 402. A portion of a PED is insertable into flexible member 401.

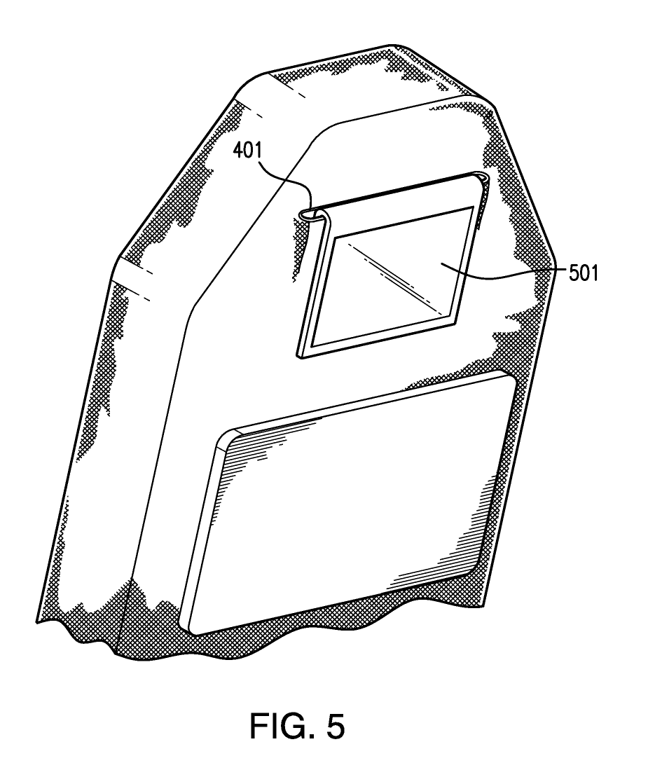

FIG. 5 is an illustrative depiction of the embodiment of FIG. 4 after the insertion of a portion of PED 501.

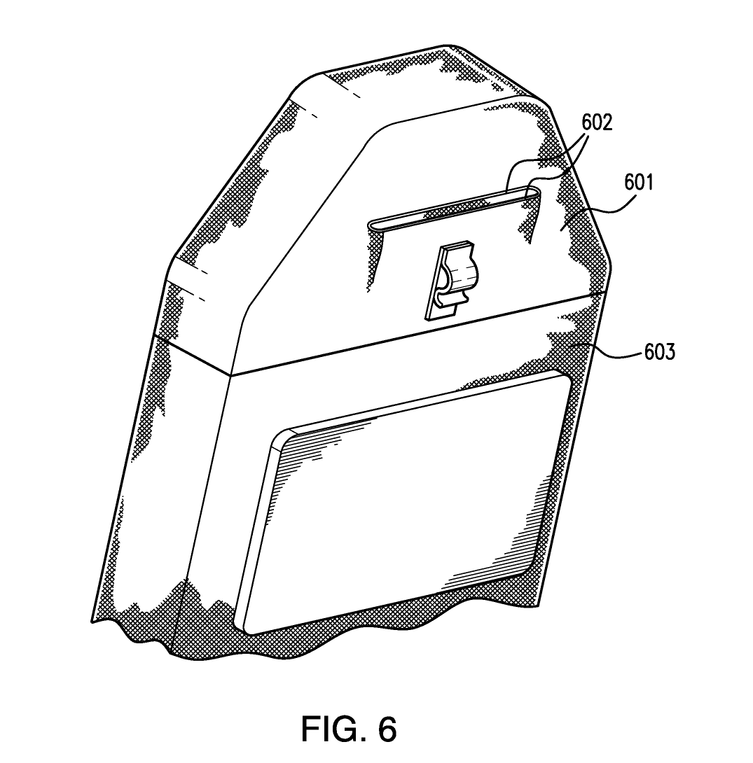

FIG. 6 is an illustrative depiction of another embodiment, in which removable cover 601 serves as a support for flexible member 602. In the embodiment, removable cover 601 can be fit over existing seatback 603. Such an embodiment may be useful in selectively retrofitting existing seats at a lower cost and with less effort than certain other implementations.

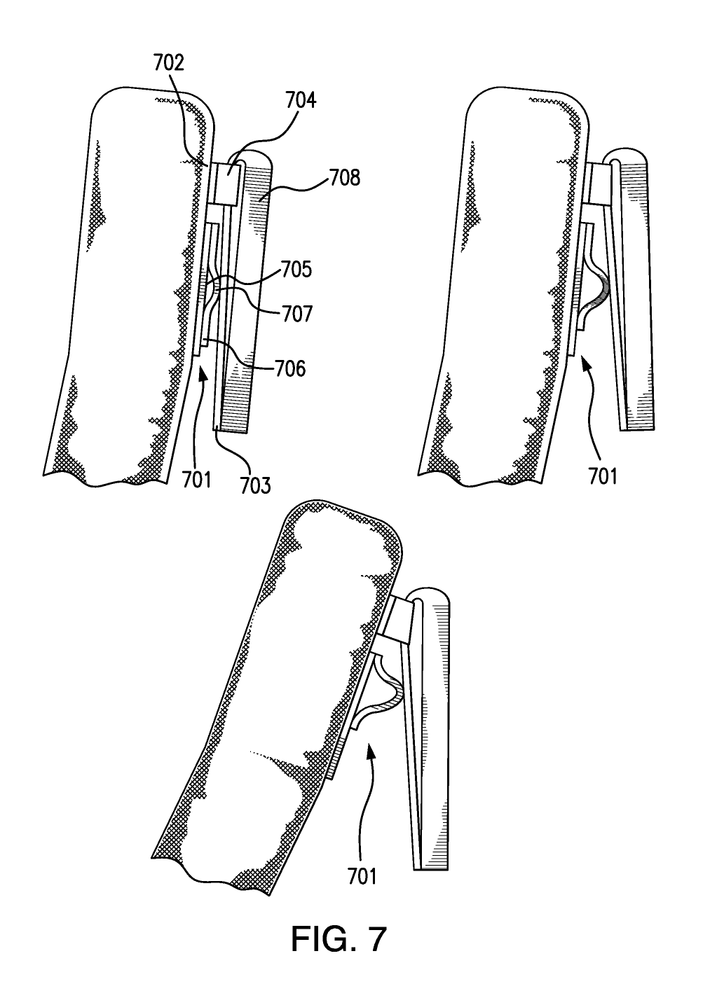

FIGS. 7(A)-(C) are illustrative depictions of an adjustment mechanism in use in various positions. Adjustment mechanism 701 is attached to support 702, which in the embodiment is a seatback. PED portion 703 is inserted into flexible member 704. Adjustment mechanism includes loop member 705, which is affixed to support 702, and hook member 706. Hook member 706 is adjustable to form bump 707 that protrudes from support 702 for the purpose of adjusting the viewing angle of PED 708. Loop member 705 and hook member 706 can be easily reattached together to adjust the size of bump 707. For instance, FIG. 7(A) depicts adjustment mechanism 701 at a relatively minimal position, providing only a slight amount of offset to PED 703. FIG. 7(B) depicts adjustment mechanism 701 at a slightly higher offset. Bump 707 protrudes from support 702 and supports PED 708 so as to adjust the viewing angle of the display 708. Such functionality can accommodate unusual viewing preferences, such as a particularly tall individual who would otherwise view the display of PED 708 at an undesirable angle. FIG. 7(C) depicts adjustment mechanism 701 at a high position, providing significant offset to PED 708. Such an offset may be sufficient so that a comfortable viewing angle may be maintained by the passenger even while the seat in front of them is in a fully reclined position. In the embodiment, the offset allows the display of PED 703 to be substantially oriented towards the natural viewing angle of the passenger even though the seat to which PED 708 is attached is reclined. Such functionality is advantageous in passenger vehicles, such as aircraft, that have reclining seats.

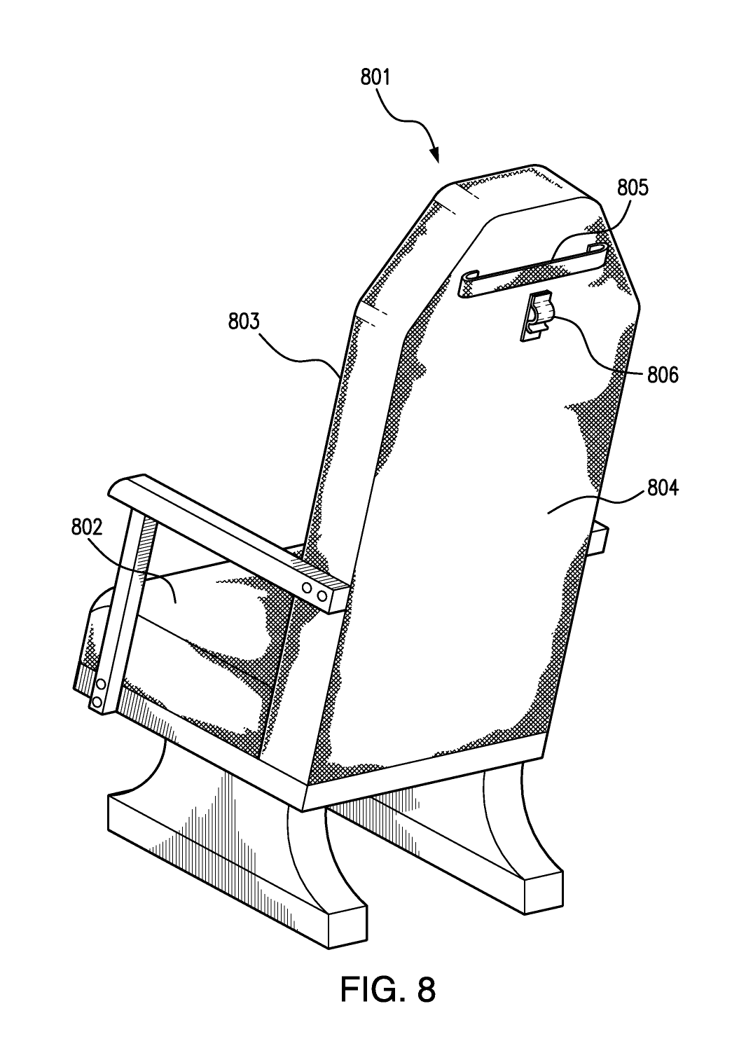

FIG. 8 is an illustrative depiction of another embodiment. Aircraft passenger seat 801 has seat pan 802, which is connected to seatback 803 which has back portion 804. Flexible member 805 is connected to back portion 804 and has an opening into which a portion of a PED can be inserted. Adjustment mechanism 806 allows the adjustment of the orientation of a PED when it is inserted.

Although the disclosed subject matter has been described and illustrated with respect to embodiments thereof, it should be understood by those skilled in the art that features of the disclosed embodiments can be combined, rearranged, etc., to produce additional embodiments within the scope of the invention, and that various other changes, omissions, and additions may be made therein and thereto, without parting from the spirit and scope of the present invention.

What is claimed is:

1. A display apparatus for a portable electronic device (PED), comprising:
a flexible member having a first end and an opposing second end with a mid-portion disposed there-between; and
said first end and said second end affixed to a support with said mid-portion spaced from said support by a gap wherein a portion of said PED is insertable into said gap.

2. The apparatus according to claim 1, further comprising an adjuster mechanism effective to allow the orientation of said PED to be adjusted.

3. The apparatus according to claim 2 wherein said adjuster mechanism is a repositionable flexible strap.

4. The apparatus according to claim 3 wherein said repositionable flexible strap is a hook and loop device, having a hook strap and a loop strap; and
one of said hook strap or loop strap being affixed to said support, the other of said hook strap and said loop strap being affixable to the one of said hook strap or said loop strap that is affixed to said support, in a manner effective to form a bump that protrudes from said support.

5. The apparatus according to claim 3 wherein said adjuster mechanism is effective to allow said PED to be sufficiently re-oriented when said support is in a reclined position.

6. The apparatus according to claim 2 wherein said apparatus is positioned within a passenger aircraft and said support is the seatback of a passenger seat.

7. The apparatus according to claim 6 wherein said portion of said PED is a hinge cover.

8. The apparatus according to claim 1 wherein said support is a removable covering for a passenger seat.

9. The apparatus according to claim 1 wherein said support is a removable harness for a passenger seat.

10. A display apparatus for a portable electronic device (PED), comprising:
a flexible member that is a substantially horizontal slit in a support; and
wherein a portion of said PED is insertable into said slit.

11. The apparatus according to claim 10, further comprising an adjuster mechanism effective to allow the orientation of said PED to be adjusted.

12. The apparatus according to claim 11 wherein said adjuster mechanism is a repositionable flexible strap.

13. The apparatus according to claim 12 wherein said repositionable flexible strap is a hook and loop device, having a hook strap and a loop strap; and
one of said hook strap or loop strap being affixed to said support, the other of said hook strap and said loop strap being affixable, to the one of said hook strap or said loop strap that is affixed to said support, in a manner effective to form a bump that protrudes from said support.

14. The apparatus according to claim 11 wherein said adjuster mechanism is effective to allow said PED to be sufficiently re-oriented when said support is in a reclined position.

15. The apparatus according to claim 12 wherein said apparatus is positioned within a passenger aircraft and said support is the seatback of a passenger seat.

16. The apparatus according to claim 15 wherein said portion of said PED is a hinge cover.

17. The apparatus according to claim 10 wherein said support is a removable covering for a passenger seat.

18. A passenger seat for an aircraft capable of presenting a PED, comprising:
a seat pan;
a seat back connected to said seat pan and having a back portion; and
a flexible member disposed on said back portion and having an opening wherein a portion of said PED is insertable into said opening.

19. The passenger seat according to claim 18, wherein said opening is formed by a flexible member having a first end attached to said seatback at a first connection point and a second end attached to said seatback at a second connection point.

20. The passenger seat according to claim 18, wherein said opening is a substantially horizontal slit in said seatback.

21. The passenger seat according to claim 19, further comprising an adjustment mechanism attached to said back portion; and
said adjustment mechanism being effective to adjust the orientation of said PED.

22. The passenger seat according to claim 20, further comprising an adjustment mechanism attached to said back portion; and
said adjustment mechanism being effective to adjust the orientation of said PED.
